(19) United States
(12) Patent Application Publication
(10) Pub. No.: US 2010/0024207 A1
(43) Pub. Date: Feb. 4, 2010

(54) SURFACE-MOUNT TECHNOLOGY NOZZLE

(75) Inventor: CHENG LIU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/329,620

(22) Filed: Dec. 7, 2008

(30) Foreign Application Priority Data
Jul. 31, 2008 (CN) 200810303287.X

(51) Int. Cl. H05K 13/04

(52) U.S. Cl. 29/740; 29/743

(57) ABSTRACT

AN SMT nozzle is provided for picking up an SMD. The nozzle includes a suction portion and a supporting arm extending from a side of the suction portion. The suction portion forms an engaging end configured for abutting against the SMD, and defines a suction passage with an opening in the engaging end. The supporting arm form at least one supporting end spaced from the engaging end of the suction portion and configured for abutting against the SMD.

### BACKGROUND

1. Technical Field

The present invention relates to surface-mount technology (SMT) and, more particularly, to a nozzle for picking up surface-mount devices (SMDs).

2. Description of Related Art

SMT are widely used in electronic industry for printed circuit board (PCB) assembly. SMT equipment includes a pneumatic suction nozzle for picking up SMDs from a tape or a tray, and placing them onto an appropriate position of a PCB. When an SMD is picked up and place onto the PCB by the nozzle, an engaging end of the nozzle abuts against a central area of the SMD to apply a suction force or a pressing force to the SMD. However, since the engaging end of the nozzle can only contact a limited area of the SMD, the SMD is prone to be tilted and misplaced when placed on the PCB. It is even more problematic when the SMD has an irregular central area and the engaging end of the nozzle has to be applied to an area apart away from the central area of the SMD in order to pick the SMD up.

### BRIEF DESCRIPTION OF THE DRAWINGS

FIG. 1 is a cross-sectional view of a first exemplary embodiment of a nozzle.

FIG. 2 is a cross-sectional view of the nozzle of FIG. 1 picking up an SMD.

FIG. 3 is a cross-sectional view of a second exemplary embodiment of a nozzle picking up an SMD.

### DETAILED DESCRIPTION

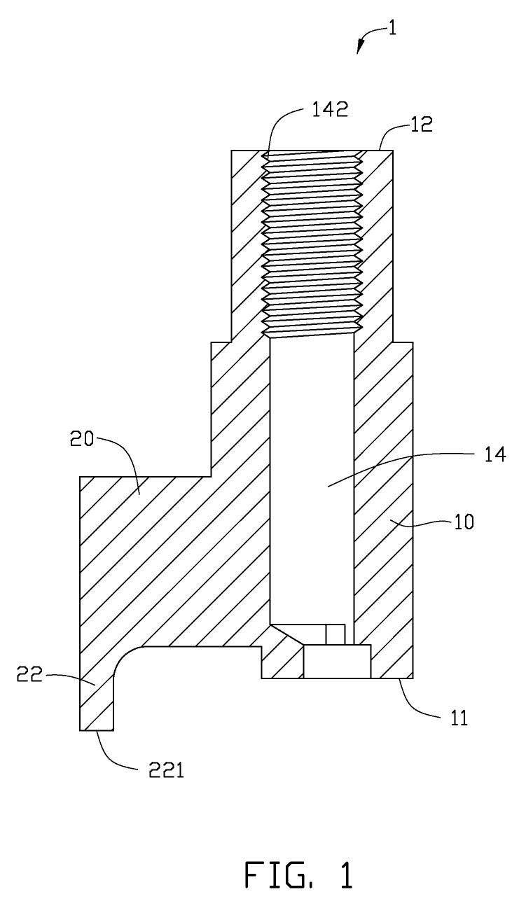

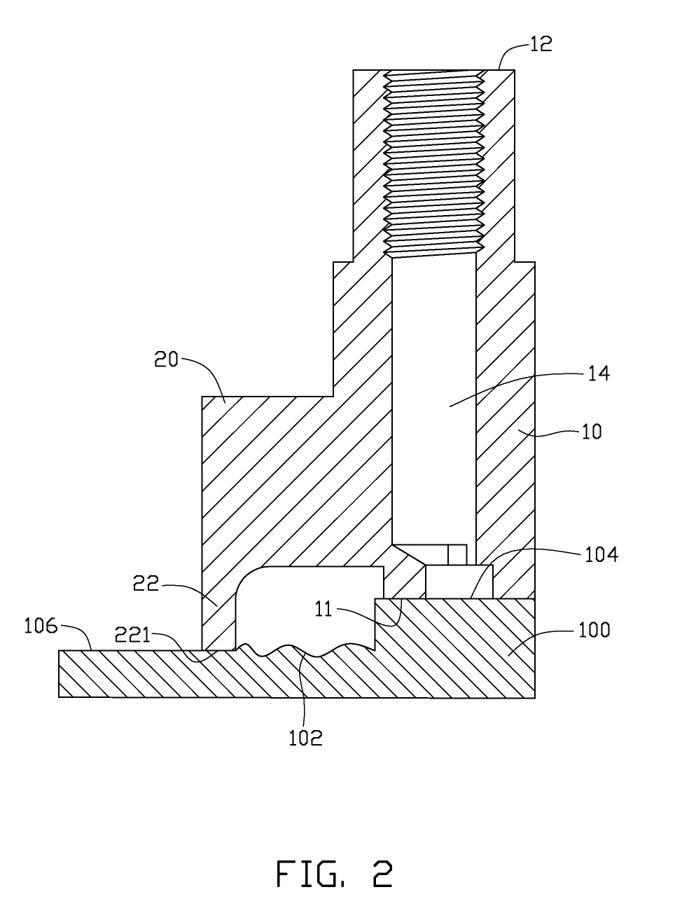

Referring to FIGS. 1 and 2, a nozzle 1 in accordance with a first embodiment is provided for picking up an SMD 100 with pneumatic suction. The nozzle 1 includes a suction portion 10 and a supporting arm 20 extending from a side of the suction portion 10. The suction portion 10 forms an engaging end 11 and a connecting end 12 opposite to each other. A suction passage 14 is defined in the suction portion 10 with two openings in the engaging end 11 and the connecting end 12, respectively. An inner thread 142 is formed in the suction passage 14 near the connection end 12 for connecting the nozzle 1 to a pneumatic suction device (not shown). The supporting arm 20 includes a positioning portion 22 with a supporting end 221. The engaging end 11 and the supporting end 221 are parallel plane surfaces and spaced from each other.

Referring also to FIG. 2, the upper surface of the SMD 100 includes a plurality of protrusions and dents at the middle portion 102, and a first plane portion 104 and a second plane portion 106 at opposite sides of the middle portion 102. To pick up the SMD 100, the engaging end 11 of the suction portion 10 abuts against the first plane portion 104, and the supporting end 221 of positioning portion 22 abuts against the second plane portion 106. When the SMD 100 is picked up or pressed onto a PCB, the nozzle 1 always abuts against both the first and the second plane portions 104 and 106 at opposite sides of the middle portion 102 of the SMD 100, therefore, the SMD 100 is prevented from being tilted and misplaced.

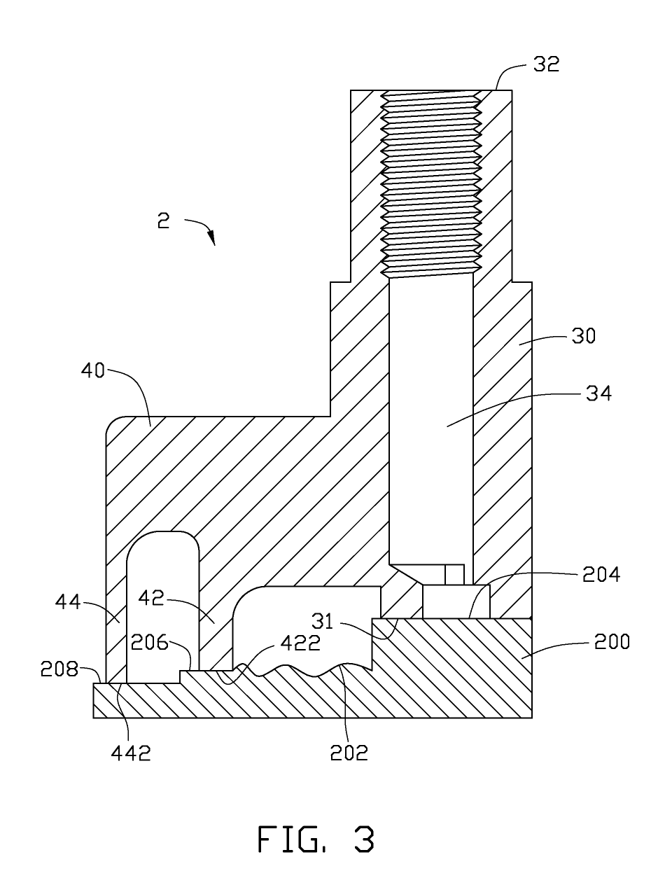

FIG. 3 shows a nozzle 2 in accordance with a second embodiment for picking up an SMD 200. The upper surface of the SMD 200 includes a plurality of protrusions and dents at the middle portion 202, a first plane portion 204, a second plane portion 206 and a third plane portion 208. The first, the second and the third plane portiona 204, 206 and 208 are stepped and parallel to each other. The nozzle 2 includes a suction portion 30 and a supporting arm 40 protruding from a side of the suction portion 30. The suction portion 30 forms an engaging end 31 and a connecting end 32 opposite to each other. A suction passage 34 is defined in the suction portion 10 with two openings in the engaging end 31 and the connecting end 32, respectively. The supporting arm 40 includes a positioning portion 42 with supporting end 422 and a positioning portion 44 with a supporting end 442. The engaging end 31 and the two supporting ends 422, 442 are parallel plane surfaces and spaced from each other. When the SMD 200 is picked up or pressed onto a PCB, the engaging end 31, and the two supporting ends 422, 442 of the nozzle 2 correspondingly abut against the first, second and third plane portions 202, 204 and 206 of SMD 200, therefore, the SMD 200 is prevented from being tilted and misplaced.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A surface-mount technology (SMT) nozzle for picking up a surface-mount technology device (SMD), the SMT nozzle comprising:
a suction portion forming an engaging end configured for abutting against the SMD, and defining a suction passage with an opening in the engaging end for sucking the SMD; and
a supporting arm extending from a side of the suction portion and forming at least one supporting end spaced from the engaging end of the suction portion and configured for abutting against the SMD to provide a balanced support for the SMD.

2. The nozzle as described in claim 1, wherein the supporting arm comprises a protrusion formed at the side of the suction portion and at least one position portion extending from the protrusion, the at least one supporting end is formed on the positioning portion.

3. The nozzle as described in claim 1, wherein the engaging end and the at least one supporting end are parallel plane surfaces and spaced from each other.

4. The nozzle as described in claim 1, wherein the suction portion comprises a connecting end opposite to the engaging end, the suction passage has another opening defining in the connecting end.

5. The nozzle as described in claim 1, wherein the upper surface of the SMD comprises a plurality of protrusions and dents at the middle portion, and at least two plane portions at opposite sides of the middle portion, the plane portions are stepped and parallel to each other, the engaging end and the at least one supporting end of the nozzle are configured to abut against the plane portions of the SMD.

6. A surface-mount technology (SMT) nozzle for picking up a surface-mount technology device (SMD), the SMD having a curved surface at the middle thereof, and two flat surfaces at two opposite sides of the curved surface, the SMT nozzle comprising:
a suction portion forming an engaging end configured for abutting against one of the two flat surfaces of the SMD for picking up the SMD; and
a supporting arm extending from a side of the suction portion and forming one supporting end spaced from the engaging end of the suction portion, and the supporting end being configured for abutting against the other one of the two flat surfaces of the SMD to providing a balance force to the SMD.

7. The nozzle as described in claim 6, wherein the engaging end and the supporting end are one coplanar for abutting against the two stepped flat surfaces of the SMD.
